(19) United States
(12) Patent Application Publication
(10) Pub. No.: US 2011/0045613 A1
(43) Pub. Date: Feb. 24, 2011

(54) METHOD OF MANUFACTURING SEMICONDUCTOR DEVICE AND EXPOSURE DEVICE

(76) Inventor: Masaru SUZUKI, Mie (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/793,347

(22) Filed: Jun. 3, 2010

(30) Foreign Application Priority Data
Aug. 18, 2009 (JP) 2009-188816

(51) Int. Cl. H01L 21/66; G03B 27/52

(52) U.S. Cl. 438/7; 355/55; 257/E21.525

(57) ABSTRACT

A method of manufacturing a semiconductor device according to an embodiment includes acquiring focus values measured for regions having different reflectance respectively due to films formed at a lower location than a resist formed above a semiconductor substrate, the focus values including a first focus value acquired at a first region of the regions having a lower reflectance and a second focus value acquired at a second region of the regions having a higher reflectance than the first region and bringing the second focus value closer to the first focus value, and carrying out an exposure processing.

### CROSS-REFERENCE TO RELATED APPLICATIONS

This application is based upon and claims the benefit of priority from prior Japanese Patent Application No. 2009-188816, filed on Aug. 18, 2009, the entire contents of which are incorporated herein by reference.

### FIELD

Embodiments described herein relate generally to an exposure device and a method of manufacturing semiconductor device.

### BACKGROUND

As a conventional technique, a position measurement method is known, the method including a step of projecting slit images to a focus measurement point on a resist formed in a substrate and two focus measurement points sandwiching the focus measurement point therebetween, a step of calculating a reflectance distribution, a position of the center of gravity and a focus error in order due to an intensity of reflection lights obtained from the three focus measurement points, and a step of correlating the calculated focus errors with coordinates of the focus measurement points and storing them on a memory device. This method is disclosed in, for example, International Publication WO-A1-2004-047156.

According to the position measurement method, the focus error is preliminarily known so that the focus error can be eliminated from a measured value measured by using a detective light, and the substrate can be positioned in a predetermined position.

However, according to the conventional method, the focus error is calculated by the intensity of reflection lights obtained from the three focus measurement points, so that there is a problem that much time is required for the measurement.

### BRIEF SUMMARY

A method of manufacturing a semiconductor device according to an embodiment includes acquiring focus values measured for regions having different reflectance respectively due to films formed at a lower location than a resist formed above a semiconductor substrate, the focus values including a first focus value acquired at a first region of the regions having a lower reflectance and a second focus value acquired at a second region of the regions having a higher reflectance than the first region and bringing the second focus value closer to the first focus value, and carrying out an exposure processing.

A method of manufacturing a semiconductor device according to another embodiment includes dividing regions having different reflectance respectively due to films formed at a lower location than a resist formed above a semiconductor substrate into a first region having a lower reflectance and a second region having a higher reflectance than the first region based on a layout of pattern formed in the semiconductor substrate and carrying out an exposure process of the first region and the second region based on a focus value measured for the first region.

An exposure device according to another embodiment includes a light source part configured to emit an inspection light to a resist formed above a semiconductor substrate, a light detection part configured to detect a reflection light of the inspection light emitted from the light source part, a calculation part configured to calculate a focus value based on an inspection result of the light detection part, and an exposure processing part configured to bring closer to a first focus value acquired from a first region having a lower reflectance, a second focus value acquired from a second region having a higher reflectance than the first region, of focus values calculated by the calculation part, and to carry out an exposure processing.

### BRIEF DESCRIPTION OF THE DRAWING

FIG. 1 is an explanatory view schematically showing an exposure device according to a first embodiment;

FIG. 2 is a plan view schematically showing a wafer used in the first embodiment;

FIG. 3 is a plan view schematically showing focus values in a first region and a second region used in the first embodiment;

FIG. 4 is a cross-sectional view schematically showing an inspection light and a reflection light used in the first embodiment;

FIG. 5 is an explanatory view schematically showing focus values used in the first embodiment;

FIG. 6 is a cross-sectional view schematically showing the inspection light and the reflection light in case that a resist used in the first embodiment has a step;

FIG. 7 is a flow chart showing a method of manufacturing a semiconductor device according to the first embodiment; and

FIG. 8 is a flow chart showing a method of manufacturing a semiconductor device according to a second embodiment.

### DETAILED DESCRIPTION

### First Embodiment

### Composition of Exposure Device

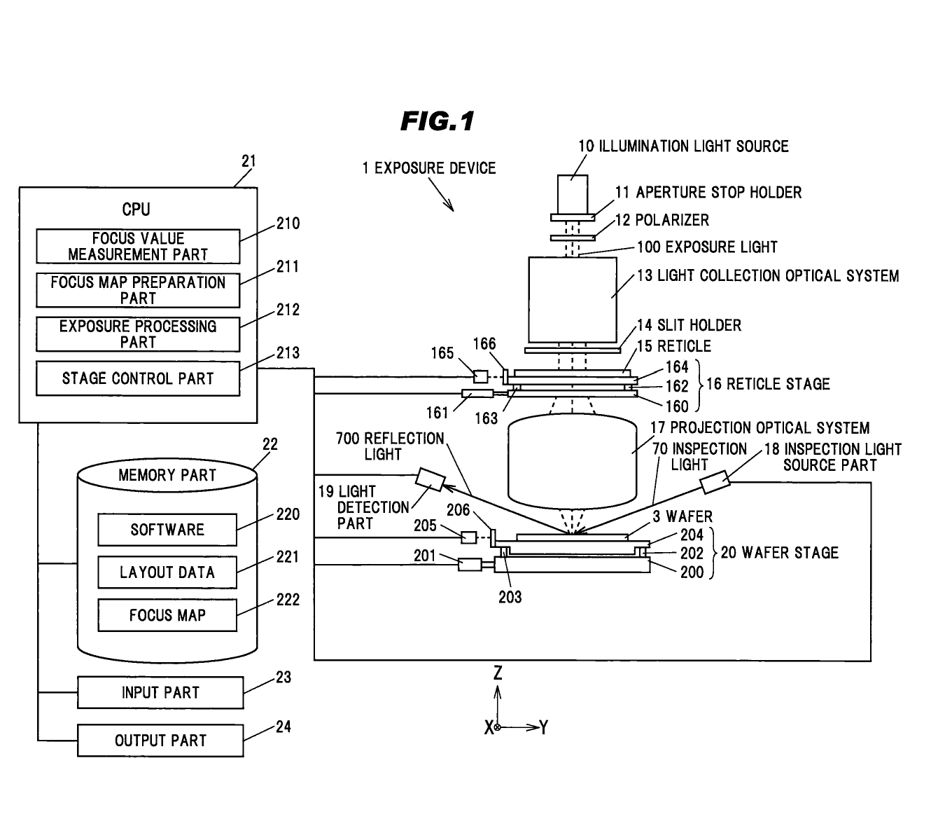

FIG. 1 is an explanatory view schematically showing an exposure device according to a first embodiment. A XYZ coordinate system shown in FIG. 1 has a Y axis along a direction in which a reticle described below and a wafer move relatively at the time of exposure, an X axis along a direction perpendicular to the Y axis direction, and a Z axis along a direction perpendicular to the X and Y axis directions, namely along a light axis direction of a projection optical system described below. In addition, the exposure device 1 is, as an example, a scan exposure device for transferring a mask pattern on the reticle onto the wafer by a step and repeat method.

The exposure device 1 roughly includes an inspection light source part 18 as a light source part for emitting an inspection light 70 to a resist formed above a wafer 3 as a semiconductor substrate, a light detection part 19 for detecting a reflection light 700 of the inspection light 70 emitted from the inspection light source part 18, a focus value measurement part 210 as a calculation part for calculating a focus value based on a detection result of the light detection part 19, and an exposure processing part 212 for bringing a focus value acquired from a region having a higher reflectance closer to a focus value acquired from a region having a lower reflectance, of the focus values measured by the focus value measurement part 210, and carrying out an exposure processing.

In addition, as shown in FIG. 1, the exposure device 1 roughly includes an illumination light source 10 for emitting an exposure light 100, an aperture stop holder 11 arranged under the illumination light source 10, a polarizer 12 for polarizing the exposure light 100, a light collection optical system 13 for collecting the exposure light 100 polarized, a slit holder 14 arranged under the light collection optical system 13, a reticle stage 16 for holding a reticle 15 arranged under the slit holder 14, a projection optical system 17 arranged under the reticle stage 16, a wafer stage 20 for holding the wafer 3 arranged under the projection optical system 17, a central processing unit (CPU) 21, a memory part 22, an input part 23 and an output part 24.

The illumination light source 10 is configured so as to emit, for example, an excimer laser such as KrF, ArF as the exposure light 100.

The reticle 15 includes, for example, a transparent substrate such as a silica glass and a light shielding film of Cr or the like formed on the transparent substrate as a mask pattern.

The reticle stage 16 roughly includes a XY stage for reticle 160, movable shafts for reticle 162, 163 arranged on the XY stage for reticle 160, and an inclined Z stage for reticle 164 connected to the XY stage for reticle 160 via the respective movable shafts for reticle 162, 163.

A reticle stage driving part 161 is connected to the reticle stage 16. The reticle stage driving part 161 scans the XY stage for reticle 160 in a horizontal direction. In addition, the reticle stage driving part 161 drives the respective movable shafts for reticle 162, 163 in a vertical direction. Consequently, the inclined Z stage for reticle 164 can be positioned in a horizontal direction by the XY stage for reticle 160 and can be arranged so as to have an inclination relative to the horizontal surface by the respective movable shafts for reticle 162, 163. A movable mirror for reticle 166 is arranged at an end portion of the inclined Z stage for reticle 164. Arrangement position of the inclined Z stage for reticle 164 is measured by a laser interferometer 165 arranged so as to face the movable mirror for reticle 166.

The wafer stage 20 roughly includes a XY stage for wafer 200, movable shafts for wafer 202, 203 arranged on the XY stage for wafer 200, and an inclined Z stage for wafer 204 connected to the XY stage for wafer 200 via the respective movable shafts for wafer 202, 203.

A wafer stage driving part 201 is connected to the wafer stage 20. The wafer stage driving part 201 scans the XY stage for wafer 200 in a horizontal direction. In addition, the wafer stage driving part 201 drives the respective movable shafts for wafer 202, 203 in a vertical direction. Consequently, the inclined Z stage for wafer 204 can be positioned in a horizontal direction by the XY stage for wafer 200 and can be arranged so as to have an inclination relative to the horizontal surface by the respective movable shafts for wafer 202, 203. A movable mirror for wafer 206 is arranged at an end portion of the inclined Z stage for wafer 204. Arrangement position of the inclined Z stage for wafer 204 is measured by a laser interferometer 205 arranged so as to face the movable mirror for wafer 206.

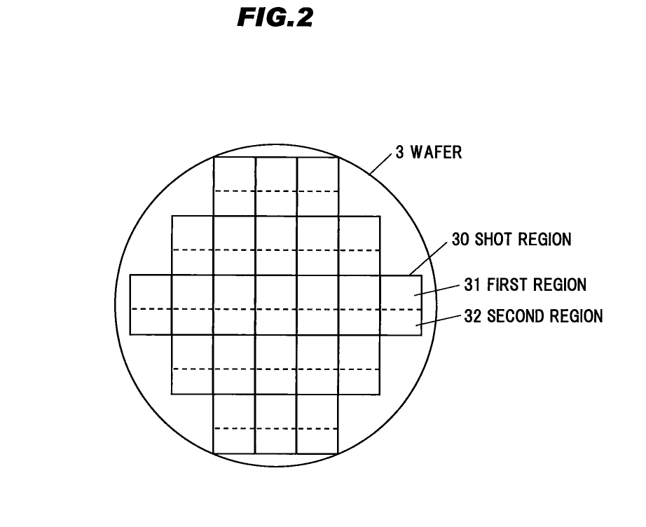

FIG. 2 is a plan view schematically showing a wafer used in the first embodiment. The mask pattern formed in the reticle 15 is reduction-projected onto the wafer 3, particularly, onto every shot region 30 of the wafer 3 as shown in FIG. 2. A first region 31 shown in FIG. 2 is, for example, a region where a film having a lower reflectance is formed at a lower location than the resist. A second region 32 shown in FIG. 2 is, for example, a region where a film having a higher reflectance than the first region 31 is formed at a lower location than the resist. For a specific example of the first and second regions 31, 32, the first region 31 is a region having

a lower density of wiring, formed at a lower location than the resist, and the second region 32 is a region having the density of wiring higher than the first region 31. In addition, the reflectance measured in the first region 31 and the second region 32 is different from each other, in case that, for example, the films formed at a lower location than the resist have a different composition from each other, or have a different film thickness from each other. Further, a plurality of the first and second regions 31, 32 can be disposed in the shot region 30.

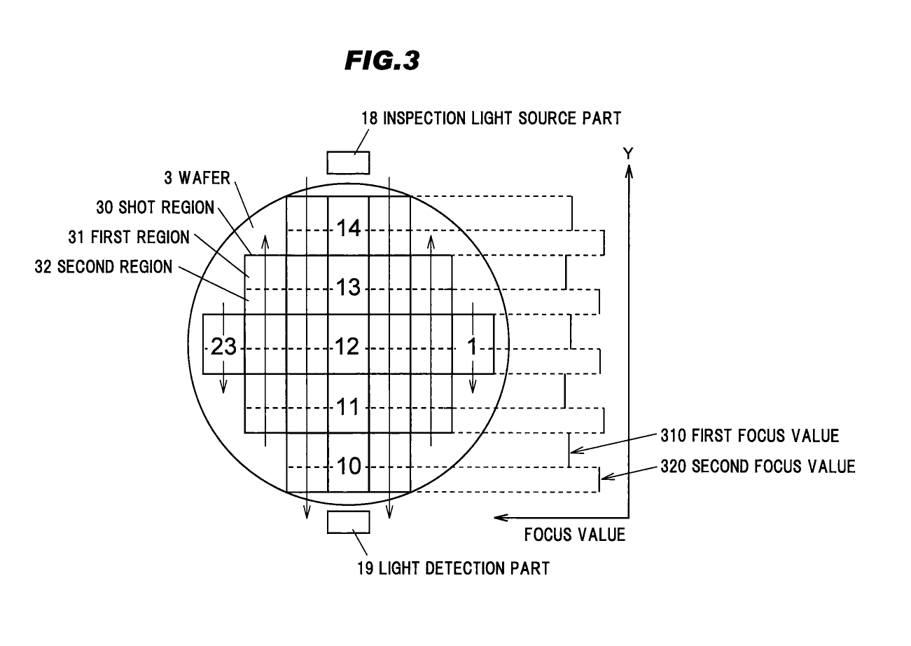

FIG. 3 is a plan view schematically showing focus values in the first region and the second region used in the first embodiment. The focus values represented as a graph in FIG. 3 show focus values of the shot regions 30 to which the numbers of “10” to “14” are provided in FIG. 3. In addition, arrow marks shown in FIG. 3 show the order of measurement of the shot regions 30. The measurement of the focus value is carried out by emitting the inspection light 70 sequentially toward measurement points of the shot regions 30 to which the numbers of “1” to “23” are provided in FIG. 3 and detecting the reflection light 700 by the light detection part 19, and the wafer 3 moves relatively to the inspection light source part 18 and the light detection part 19 via wafer stage 20.

The inspection light source part 18 is configured to have a structure that, for example, seven light sources arranged in a line. The inspection light source part 18 emits the inspection light 70 toward a plurality of the measurement points formed in the shot regions 30, and the light detection part 19 detects the reflection light 700 reflected at a surface of the resist and the like. Here, the inspection light 70 emitted from the inspection light source part 18 is a light having a wavelength that does not expose the resist.

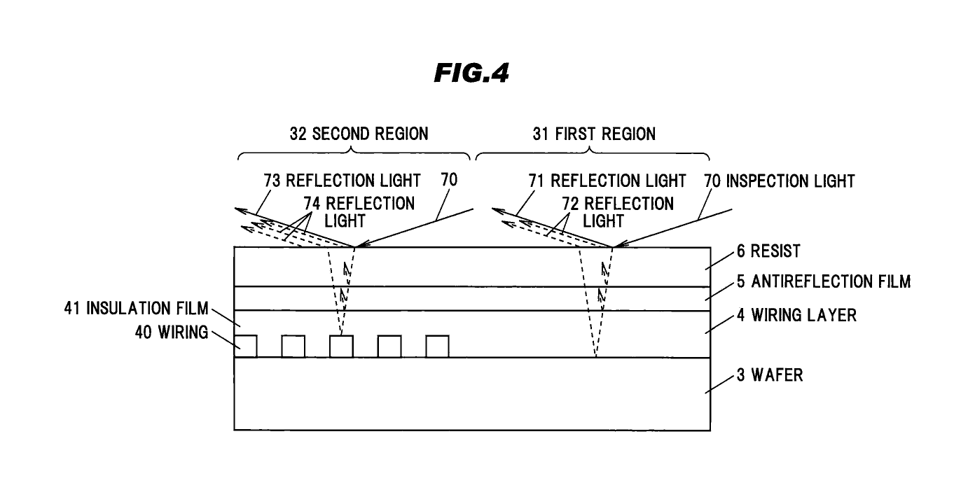

FIG. 4 is a cross-sectional view schematically showing an inspection light and a reflection light used in the first embodiment. FIG. 4 illustrates how a focus value to the first region 31 is measured and a focus value to the second region 32 is measured.

As shown in FIG. 4, the wafer 3 includes, for example, the wiring layer 4 formed on the wafer 3, an antireflection film 5 for preventing the exposure light 100 from reflecting, formed on the wiring layer 4, and the resist 6 formed on the antireflection film 5. The wiring layer 4 roughly includes a wiring 40 formed on the wafer 3 and an insulation film 41 formed so as to cover the wiring 40. The wiring 40 is, for example, a metal film that has a reflectance higher than the wafer 3, the insulation film 41, the antireflection film 5 and the resist 6. In addition, the antireflection film 5 prevents reflection of the exposure light 100 so as to enhance an accuracy of exposure process, but it is not a film for preventing reflection of the inspection light 70 emitted from the inspection light source part 18, so that the inspection light 70 transmits through the antireflection film 5 and reflects at interfaces of the films formed at a lower location and in the inside of the films.

In the first region 31, for example, the inspection light 70 made to enter the inside of the resist 6 reflects at interfaces of the films formed at a lower location than the resist 6 and in the inside of the films, the reflection light 72 from the lower films than the resist 6 and the reflection light 71 from a surface of the resist 6 are detected as the reflection light 700 at the light detection part 19, a reflectance is calculated based on the reflection light 700 and the inspection light 70, and a focus value is calculated based on the reflectance calculated. An error of the focus value is mainly caused due to the reflection light 72. In the second region 32, for example, the inspection light 70 made to enter the inside of the resist 6 reflects at interfaces of the films formed at a lower location than the resist 6, in the inside of the films and at the wiring 40 having a reflectance higher than the other films, the reflection light 74 from the lower films than the resist 6 and the reflection light 73 from a surface of the resist 6 are detected as the reflection light 700 at the light detection part 19, a reflectance is calculated based on the reflection light 700 and the inspection light 70, and a focus value is calculated based on the reflectance calculated. The reflection light 74 includes the reflection light from the wiring 40 having a higher reflectance, so that the error of the focus value in the second region 32 becomes larger than the first region 31.

For example, when one shot region 30 is divided into the first region 31 where the films formed at a lower location than the resist 6 have a lower reflectance and the second region 32 where the films formed at a lower location than the resist 6 have a higher reflectance than the first region 31, as shown in FIG. 3, the focus value measured is divided broadly into a first focus value 310 measured as a focus value in a low reflectance region and a second focus value 320 measured as a focus value in a high reflectance region.

The CPU 21 roughly includes a focus value measurement part 210 as a calculation part, a focus map preparation part 211, an exposure processing part 212 and a stage control part 213.

The focus value measurement part 210 controls the inspection light source part 18 and the light detection part 19, calculates a distance (a focus value) from a reference point along a light axis direction of the projection optical system 17 of the wafer 3 from the reflection light 700 detected by the light detection part 19, and outputs the calculated result to the focus map preparation part 211 while associating with coordinates of the reference points.

The focus map preparation part 211 corrects the focus value in each reference point measured by the focus value measurement part 210 by a correction method described below, and prepares a focus map 222 showing a distribution of the focus value while associating the corrected focus values with coordinates of the reference points.

The exposure processing part 212 controls processes in an exposure processing, various parameters and the like. Also, the exposure processing part 212 brings the second focus value 320 obtained in the second region 32 having a reflectance higher than the first region 31 closer to the first focus value 310 obtained in the first region 31 having a lower reflectance, and carries out the exposure processing.

The stage control part 213 controls the reticle stage driving part 161, the laser interferometer 165, the wafer stage driving part 201, the laser interferometer 205 and the like based on controls of the exposure processing part 212 and the focus value measurement part 210.

The memory part 22 stores a software 220, a layout data 221, and a focus map 222. The software 220 is a program necessary for the exposure processing, and measurement and correction of the focus value, and is executed by the CPU 21. The layout data 221 is a data about a layout of circuit formed on the wafer 3, and as one example, is stored in the memory part 22 via the input part 23. Further, hereinafter, it is presupposed that the software 220 has been already executed by the CPU 21.

The input part 23 is connected to, for example, an input device such as a key board, a mouse, and an external device such as a computer. The output part 24 is connected to, for example, a monitor screen display based on a liquid crystal display device, a light emitting diode or the like.

Hereinafter, a method of manufacturing a semiconductor device according to the embodiment will be explained.

(Method of Manufacturing Semiconductor Device)

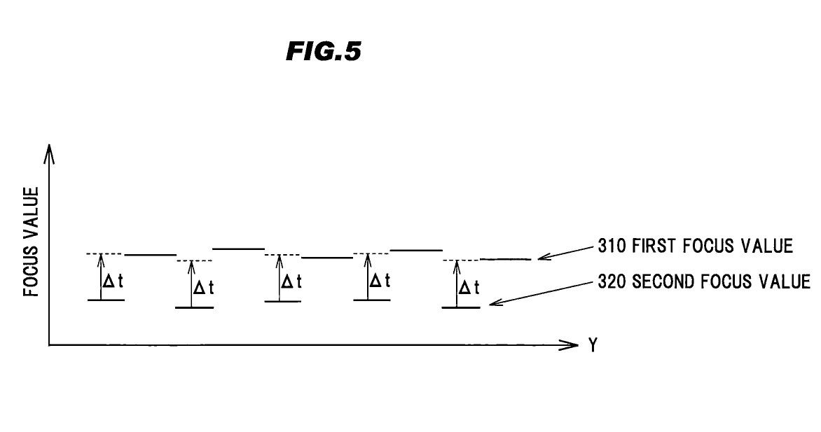

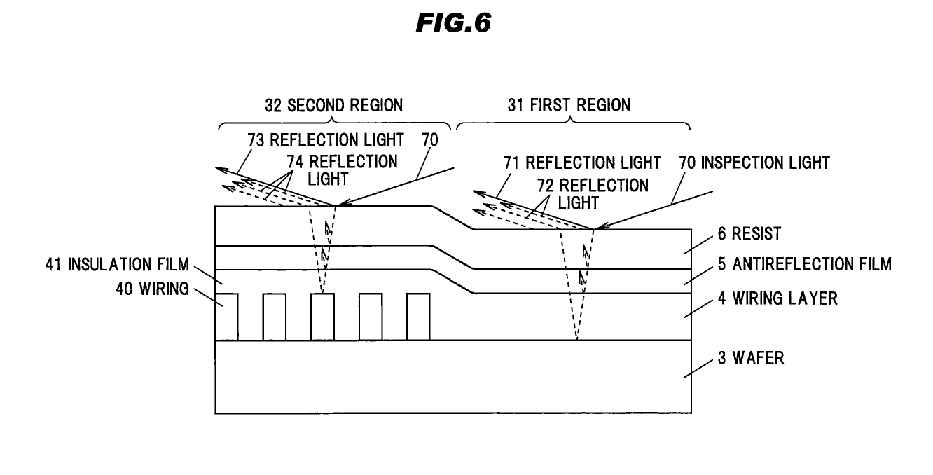

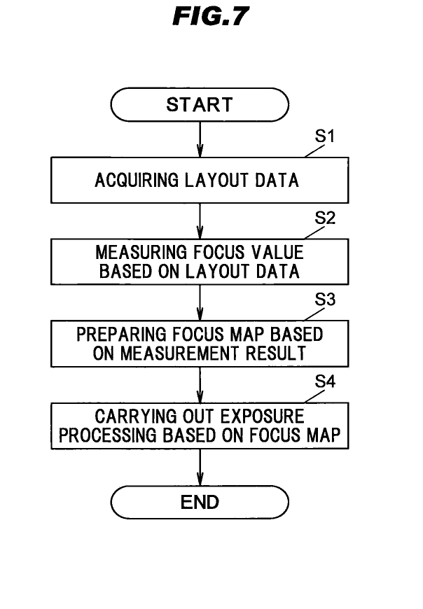

FIG. 5 is an explanatory view schematically showing focus values used in the first embodiment. FIG. 6 is a cross-sectional view schematically showing an inspection light and a reflection light in case that a resist used in the first embodiment has a step. FIG. 7 is a flow chart showing a method of manufacturing a semiconductor device according to the first embodiment. In FIG. 5, a vertical axis shows a focus value and a horizontal axis is a Y-axis.

First, the wafer 3 in which the wiring layer 4 and the like are formed at the lower location than the resist 6 is prepared, and is set to the inclined Z stage for wafer 204. Subsequently, when the CPU 21 of the exposure device 1 is directed via the input part 23 to measure the focus value, it acquires the layout data 221 about the wafer 3 from the memory part 22 (S1).

Next, the focus value measurement part 210 of the CPU 21 measures the focus value based on the layout data 221 acquired (S2).

Particularly, the focus value measurement part 210 divides the shot region 30 into the first and second regions 31, 32 based on the layout data 221, and measures the focus value in each measurement point by a step and repeat method or a method of preliminarily measuring before the exposure processing, and outputs to the focus map preparation part 211 while associating the focus values measured with coordinates of the measurement points.

Next, the focus map preparation part 211 prepares the focus map 222 based on the measurement result (S3).

Particularly, the focus map preparation part 211 carries out the correction by a correction method of bringing the second focus value 320 of the second region 32 outputted from the focus value measurement part 210 closer to the first focus value 310 of the first region 31. Subsequently, the focus map preparation part 211 prepares the focus map 222 while associating the first focus values 310 and the second focus values 320 after corrected with coordinates of each measurement points. FIG. 5 shows a correction method of adding a given correction value Δt to the second focus value 320 so as to bring the second focus value 320 closer to the first focus value 310 as one example of the correction. As a particular correction method of correcting so as to bring the second focus value 320 closer to the first focus value 310, for example, the following method can be used. Namely, one correction method is calculating an average focus value of the first focus value 310 and an average focus value of the second focus value 320 in one shot region 30, calculating a difference between them, and adding the difference calculated to the second focus value 320 so that the correction is carried out, and another correction method is calculating an approximate value of the first focus value 310 and an approximate value of the second focus value 320 by using a least-square approximation method, calculating a difference between them, and adding the difference calculated to the second focus value 320 so that the correction is carried out.

Further, with regard to the resist 6 shown in FIG. 6, for example, a wiring 40 and the like are formed at lower location than the resist 6, so that a height of the surface is varied near the boundary of the first region 31 and the second region 32. In case that the resist 6 has a step, it is difficult to determine whether the error of the focus value is caused due to the step or difference between densities of the wiring 40, consequently, for example, it is preferable that the correction method is carried out by preliminarily grasping the height of the step and then adopting a third focus value obtained by adding the height of the step to the second focus value after corrected.

In addition, in case that the wiring layer 4 is planarized by a chemical mechanical polishing (CMP) method, for example, it is preferable that the regions are divided based on whether the reflectance is high or low and the correction method is carried out.

Next, the exposure processing part 212 carries out the exposure processing to the wafer 3 based on the focus map 222 prepared (S4).

Particularly, the exposure device 1 starts a scan exposure processing by the step and repeat method. The exposure processing part 212 controls the wafer stage driving part 201 and the like based on the focus map 222 in accordance with the focus value at each measurement point via the stage control part 213, adjusts a location in the Z-axis direction of the wafer 3, inclination and the like, and then carries out the exposure processing.

Next, after the exposure processing is completed in the whole of the wafer 3, a development processing is carried out so as to form a resist pattern. Subsequently, an etching processing is carried out by using the resist pattern formed as a mask so as to etch the films formed at a lower location than the resist pattern and to form a desired pattern. Subsequently, a desired semiconductor device is obtained via well-known processes. Further, for example, in case that variation in finish of the wafer in a lot is small, it can be adopted that the focus value of the first wafer in the lot is measured so as to prepare the focus map 222 and then the exposure processing of remaining wafers in the lot is carried out base on the focus map 222.

(Advantages of First Embodiment)

According to the first embodiment, the following advantages can be obtained.

(1) A focus value of a region with a higher reflectance due to the films formed at the lower location than the resist 6 is brought closer to a focus value of a region having a lower reflectance and then an exposure processing is carried out, so that the exposure processing can be carried out with a higher degree of accuracy than a case that the exposure processing is carried out by using a focus value averaged.
(2) The focus value can be measured in a condition that the surface of the wafer is divided into the region with a higher reflectance and the region having a lower reflectance based on the layout data 221, so that the focus value can be obtained in the whole wafer 3 with a higher degree of accuracy than a case that the layout data 221 is not adopted.
(3) In an exposure device including an optical focus measurement device, the focus value can be obtained with a higher degree of accuracy by changing the software, instead of incorporating additional components in the exposure device.
(4) It is not needed to carry out a troublesome processing for calculating the focus value, so that the measurement time of the focus value can be shortened.

### Second Embodiment

The second embodiment is different from the first embodiment in terms of correcting the focus value without using the layout data. Further, in the following each embodiment, with regard to elements having the same construction and function as those in the first embodiment have, the same references as those of the first embodiment will be used, and detail explanation will be omitted.

Hereinafter, a method of manufacturing a semiconductor device according to the embodiment will be explained.

(Method of Manufacturing Semiconductor Device)

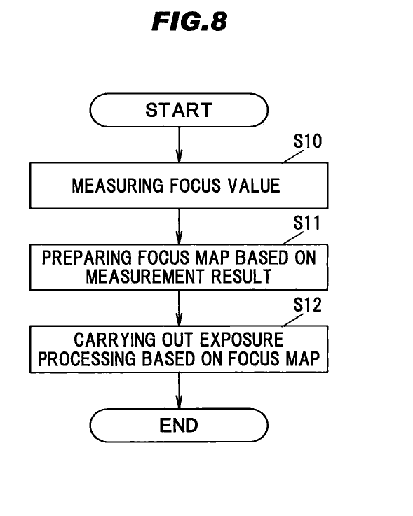

FIG. 8 is a flow chart showing a method of manufacturing a semiconductor device according to a second embodiment.

First, the wafer 3 in which the resist 6 is formed is prepared, and is set to the inclined Z stage for wafer 204. Subsequently, the focus value measurement part 210 measures the focus value in the measurement points of the wafer 3 (S10).

Particularly, the focus value measurement part 210 measures the focus value in each measurement point by a step and repeat method or a method of preliminarily measuring before the exposure processing, and outputs to the focus map preparation part 211 while associating the focus values measured with coordinates of the measurement points.

Next, the focus map preparation part 211 prepares the focus map 222 based on the measurement result (S11).

Particularly, the focus map preparation part 211, for example, divides broadly the focus values polarized according to a high or low reflectance, of the focus values outputted from the focus value measurement part 210, into small focus values and large focus values in size. Subsequently, the focus map preparation part 211 averages the large focus values and carries out the correction by using a correction method of bringing the small focus values closer to the averaged large focus values. Subsequently, the focus map preparation part 211 prepares the focus map 222 while associating the corrected small focus values and the not-corrected large focus values with coordinates of each measurement points. Further, the correction method is not limited to this, any method can be adopted, if it is a correction method of bringing the small focus values closer to the large focus values.

Next, the exposure processing part 212 carries out the exposure processing to the wafer 3 based on the prepared focus map 222 (S12).

Next, after the exposure processing is completed in the whole of the wafer 3, a development processing is carried out so as to form a resist pattern. Subsequently, an etching processing is carried out by using the resist pattern formed as a mask so as to etch the films formed at a lower location than the resist pattern and to form a desired pattern.

(Advantages of Second Embodiment)

According to the second embodiment, the following advantages can be obtained.

The correction of the focus value can be carried out without using the layout data, so that the measurement time of the focus value can be shortened in comparison with a case of using the layout data.

### Third Embodiment

The third embodiment is different from each of the above-mentioned embodiments in terms of carrying out the exposure processing by using the focus value of the region having a lower reflectance without measuring the region having a higher reflectance.

(Method of Manufacturing Semiconductor Device)

First, the wafer 3 in which the resist 6 is formed is prepared, and is set to the inclined Z stage for wafer 204. Subsequently, when the CPU 21 of the exposure device 1 is directed via the input part 23 to measure the focus value, it acquires the layout data 221 about the wafer 3 from the memory part 22.

Next, the focus value measurement part 210 measures the focus value based on the layout data 221 acquired.

Particularly, the focus value measurement part 210 divides the shot region 30 into the first and second regions 31, 32 based on the layout data 221. Subsequently, the focus value measurement part 210 measures only the first focus values 310 of the first region 31 where normal focus values can be measured, and outputs to the focus map preparation part 211 while associating the focus values measured with coordinates of the measurement points.

Next, the focus map preparation part 211 prepares the focus map 222 based on the measurement result.

Particularly, the focus map preparation part 211 prepares the focus map 222 by assigning the first focus values 310 of the first region 31 outputted from the focus value measurement part 210 to the focus values of the second region 3 adjacent to the first region 31. Further, it can be also adopted that the exposure processing of the whole of the wafer 3 is carried out by averaging the first focus values 310 in the whole of the wafer 3 and using the first focus values 310 averaged.

Next, the exposure processing part 212 carries out the exposure processing to the wafer 3 based on the focus map 222 prepared.

Next, after the exposure processing is completed in the whole of the wafer 3, a development processing is carried out so as to form a resist pattern, and subsequently, an etching processing is carried out by using the resist pattern formed as a mask so as to etch the films formed at a lower location than the resist pattern and to form a desired pattern. Subsequently, a desired semiconductor device is obtained via well-known processes.

(Advantages of Third Embodiment)

According to the third embodiment, the following advantages can be obtained.

The exposure processing is carried out by using only the focus values of the region having a lower reflectance without measuring the focus values of the region having a higher reflectance, so that the measurement time of the focus value can be shortened in comparison with a case of measuring all the measurement points.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

1. A method of manufacturing a semiconductor device, comprising:
acquiring focus values measured for regions having different reflectance respectively due to films formed at a lower location than a resist formed above a semiconductor substrate, the focus values including a first focus value acquired at a first region of the regions having a lower reflectance and a second focus value acquired at a second region of the regions having a higher reflectance than the first region; and
bringing the second focus value closer to the first focus value, and carrying out an exposure processing.

2. The method of manufacturing a semiconductor device according to claim 1, wherein the second region is a region that has a density of wirings higher than the first region, the wirings being formed at the lower location than the resist.

3. The method of manufacturing a semiconductor device according to claim 2, wherein the second region is a region that has a height from a surface of the semiconductor substrate to a surface of the resist higher than the first region, and a difference of height between the first region and the second region is added to the second focus value and then the exposure processing is carried out.

4. The method of manufacturing a semiconductor device according to claim 1, wherein the exposure processing is carried out based on the first focus value and the second focus value to which a first correction value is added, the first correction value being a difference between an average of the first focus value and an average of the second focus value.

5. The method of manufacturing a semiconductor device according to claim 1, wherein the exposure processing is carried out based on the first focus value and the second focus value to which a second correction value is added, the second correction value being a difference between an approximate value of the first focus value and an approximate value of the second focus value which are acquired by a least-square approximation method.

6. The method of manufacturing a semiconductor device according to claim 1, wherein the exposure processing is carried out based on the first focus value and the second focus value to which a third correction value is added, the third correction value being a difference between an average of the first focus value and the second focus value.

7. The method of manufacturing a semiconductor device according to claim 1, wherein the first region and the second region are divided based on a layout of pattern formed in the semiconductor substrate.

8. The method of manufacturing a semiconductor device according to claim 1, wherein the exposure processing is carried out based on a focus map prepared based on the first focus value and the second focus value, the focus map showing a distribution of the focus value on the semiconductor substrate.

9. The method of manufacturing a semiconductor device according to claim 8, wherein the exposure processing is carried out based on the focus map prepared for the semiconductor substrate, when it is carried out to the other semiconductor substrate different from the semiconductor substrate.

10. A method of manufacturing a semiconductor device, comprising:
dividing regions having different reflectance respectively due to films formed at a lower location than a resist formed above a semiconductor substrate into a first region having a lower reflectance and a second region having a higher reflectance than the first region based on a layout of pattern formed in the semiconductor substrate; and
carrying out an exposure processing of the first region and the second region based on a focus value measured for the first region.

11. The method of manufacturing a semiconductor device according to claim 10, wherein the second region is a region that has a density of wirings higher than the first region, the wirings being formed at the lower location than the resist.

12. The method of manufacturing a semiconductor device according to claim 10, wherein the exposure processing is carried out based on a focus map which is prepared to show a distribution of the focus value on the semiconductor substrate.

13. The method of manufacturing a semiconductor device according to claim 12, wherein the focus map is prepared by assigning the focus value measured in the adjacent first region to the second region.

14. The method of manufacturing a semiconductor device according to claim 12, wherein the exposure processing is carried out based on the focus map prepared for the semiconductor substrate, when it is carried out to the other semiconductor substrate different from the semiconductor substrate.

15. An exposure device, comprising:
a light source part configured to emit an inspection light to a resist formed above a semiconductor substrate;
a light detection part configured to detect a reflection light of the inspection light emitted from the light source part;
a calculation part configured to calculate a focus value based on an inspection result of the light detection part; and
an exposure processing part configured to bring closer to a first focus value acquired from a first region having a lower reflectance, a second focus value acquired from a second region having a higher reflectance than the first region, of focus values calculated by the calculation part, and to carry out an exposure processing.

16. The exposure device according to claim 15, wherein the exposure processing part brings the second focus value of the second region that has a density of wirings higher than the first region, the wirings being formed at a lower location than the resist, closer to the first focus value, and carries out the exposure processing.

17. The exposure device according to claim 16, wherein the exposure processing part adds a difference of height between the first region and the second region to the second focus value of the second region that has a height from a surface of the semiconductor substrate to a surface of the resist higher than the first region, and carries out the exposure processing.

18. The exposure device according to claim 15, wherein the exposure processing part carries out the exposure processing based on the first focus value and the second focus value to which a first correction value is added, the first correction value being a difference between an average of the first focus value and an average of the second focus value.

19. The exposure device according to claim 15, wherein the exposure processing part carries out the exposure processing based on the first focus value and the second focus value to which a second correction value is added, the second correction value being a difference between an approximate value of the first focus value and an approximate value of the second focus value which are acquired by a least-square approximation method.

20. The exposure device according to claim 15, wherein the exposure processing part carries out the exposure processing based on the first focus value and the second focus value to which a third correction value is added, the third correction value being a difference between an average of the first focus value and the second focus value.
